(19) United States
(12) Patent Application Publication
(10) Pub. No.: US 2008/0277739 A1
(43) Pub. Date: Nov. 13, 2008

(54) Finfet Transistors

(75) Inventor: Gilberto Curatola, Korbek-Lo (BE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/090,977

(22) PCT Filed: Oct. 10, 2006
(86) PCT No.: PCT/IB06/53720

§ 371 Date: Apr. 21, 2008

(30) Foreign Application Priority Data
Oct. 25, 2005 (EP) 05109955.4

(51) Int. Cl. H01L 27/088; H01L 21/8234; G11C 11/34

(52) U.S. Cl. 257/393; 438/275; 365/182; 257/E27.06

(57) ABSTRACT

A fin FET array includes a number of fins 12 and a switch FET 52 between fins 12. The switch FET 52 acts to divide the transistor array into first 42 and second 44 FINFET regions having first 46 and second 48 gate electrodes controllably connected through the switch FET 52. Suitable voltages applied between the gate of the switch FET and the substrate 10 can allow the fin FET array either to act as a plurality of separate FETs or as a single device. A method of making the fin FET array to reduce the number of additional steps to fabricate the switch FET 52 is also described.

The invention relates to a semiconductor device including of FINFETs (fin field effect transistors) and to a method of making the semiconductor device.

As the channel length of semiconductor devices becomes increasingly short the doping needed for such devices combined with the short channel length results in device characteristics which can be seriously degraded, known as the “short channel effect”.

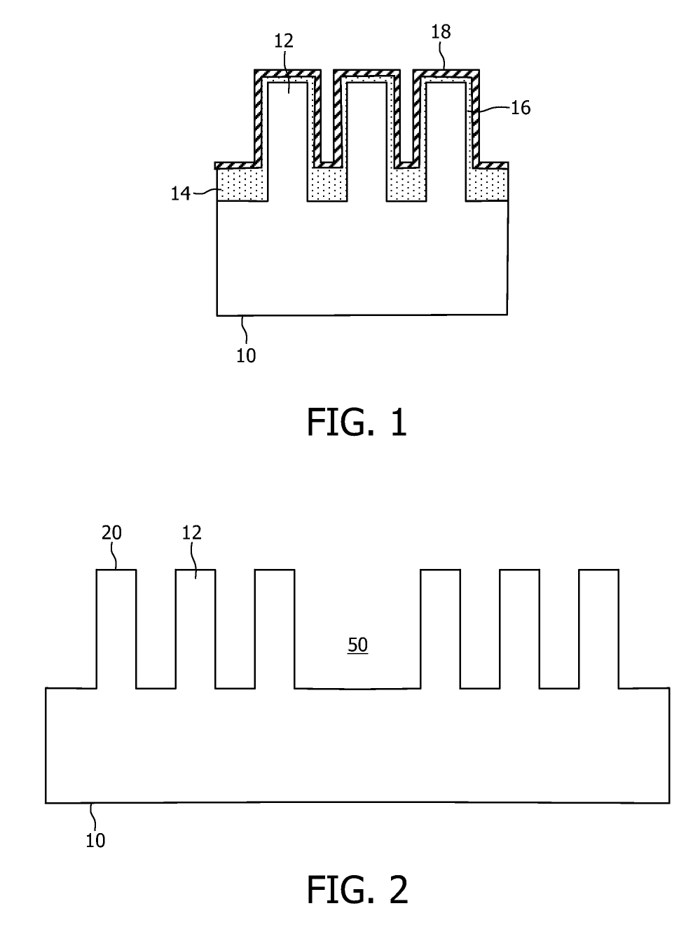

One approach to this problem is a FINFET (fin field effect transistor) which is a field effect transistor with a plurality of fins. FIG. 1 illustrates a FINFET. Substrate 10 has a plurality of fins 12 extending vertically from the substrate and laterally across the substrate. The fins extend longitudinally in the direction into the page of FIG. 1. The fins are separated by buried oxide (BOX) layer 14. A gate dielectric 16 extends over the top of each fin 12 between the BOX layers 14, and a gate 18 extends over the gate dielectric.

Longitudinally spaced source and drain contacts (not shown) are provided on either end of the gate 18 and the gate controls conduction between source and drain.

A common gate voltage may be applied to all gate electrodes in parallel. With an appropriate gate voltage, inversion layers are formed on either side of the fin, controlled by the two gates one on either side. The use of two gates instead of one reduces the short channel effect. Further the provision of two inversion layers, one on either side of the fin, can increase current carrying capacity.

While the conventional bulk MOSFET is still considered for a 45 nm technology, with a gate length less than 50 nm, the FinFET is instead considered the most appealing (and probably the only) solution from an industrial perspective to follow the International Technology Roadmap for Semiconductors (ITRS) roadmap for the 32 nm node and below. Indeed, a key point is the better control of short channel effects due to a multi-gate architecture.

However, such a structure has limited uses and it would be desirable to provide a device to have more flexibility as well as a method of making it.

According to the invention there is provided a semiconductor device, comprising:

a plurality of fin field effect transistors having sources, drains and gates, the fin field effect transistors including a first fin field effect transistor region with a common gate and a second fin field effect transistor region with a common gate; and

a switch field effect transistor between the first fin field effect transistor region and the second fin field effect transistor region, the switch field effect transistor having a source connected to the gates of one of the first and second fin field effect transistor regions and a drain connected to the other of the first and second fin field effect transistor regions, the switch field effect transistor having a gate so that the voltage on the gate of the switch field effect transistor can be controlled to selectably connect the gates of the first and second fin field effect transistor regions together.

By providing a switch transistor between first and second gate regions the gate regions can be connected together to operate in parallel or to operate separately as required.

A control voltage can be applied to a gate of the switch FET and used to control the switch FET in conjunction with the voltage applied to the silicon substrate.

The invention also relates to a method of operation of the semiconductor device as set out above including:

applying a voltage between the substrate and the gate of the switch field effect transistor to control the switch field effect transistor to be selectably in a single unit mode of operation or a multiple unit mode of operation; wherein:

in the single unit mode of operation the switch field effect transistor is switched on to connect the regions of the switch field effect transistor so that the switch field effect transistor operates as a single unit;

in the multiple unit mode of operation the switch field effect transistor is switched off to disconnect the regions of the switch field effect transistor so that the switch field effect transistor operates as a plurality of units.

In another aspect, the invention relates to a method of making a semiconductor device as set out above.

Preferably, the method includes:

providing a semiconductor substrate having a first major surface;

etching a plurality of fins into the first major surface of the substrate, the fins being laterally spaced and extending longitudinally along the first major surface for forming the fin field effect transistors, the fins defining at least one space between fins for forming the switch fin field effect transistor;

depositing oxide to form a buried oxide layer between the fins;

forming a gate dielectric over the fins;

forming a gate dielectric of the switch field effect transistor in the space between fins;

depositing a gate conductor over the gate dielectric over the fins to form the gate of the fin field effect transistors; and

forming a gate over the gate dielectric of the switch field effect transistor.

For a better understanding of the invention, embodiments will now be described, with reference to the accompanying drawings, in which:

FIG. 1 shows a prior art FINFET;

FIGS. 2 to 6 show stages in the manufacture of a FINFET according to a first embodiment of the invention; and

FIG. 7 illustrates a second embodiment of the invention.

Like components are given the same reference numerals in the different Figures. The Figures are schematic and not to scale.

A semiconductor substrate 10 is provided having a first major surface 20. A plurality of fins 12 are patterned by etching the first major surface 20. The fins 12 extend vertically into the substrate 10 from the first major surface and extend longitudinally along the surface 20 in the direction into the paper in FIG. 1. The plurality of fins are arranged laterally across the first major surface 20. A gap 50 is left between some adjacent pairs of fins for forming a switch FET 52 later.

The skilled person will be aware of many techniques for patterning surfaces, for example by depositing photoresist, patterning the photoresist using a mask, developing the photoresist to create a photoresist pattern, using reactive ion etching to etch the regions not covered by the photoresist pattern, and removing the remainder of the photoresist. Alternatives include using a hard mask, or using a wet etch. Since the skilled person is already aware of many suitable patterning techniques, they will not be described in detail here.

The above steps result in the arrangement shown in FIG. 2 (side view).

A buried oxide layer 14 is then formed between the fins. The oxide layer 14 is then etched away in the gap 50 for forming the switch FET.

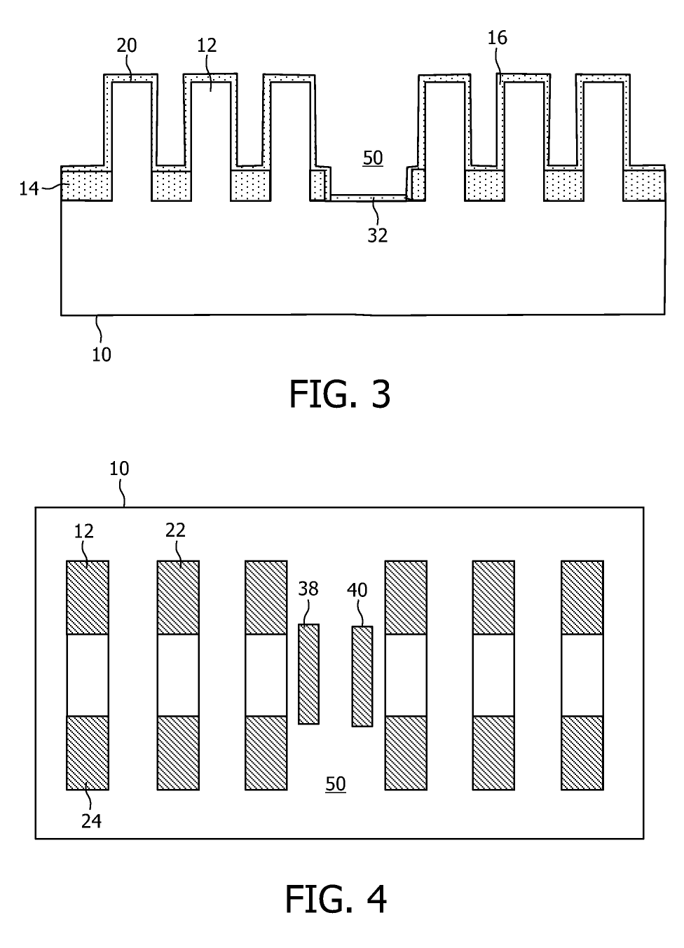

A high quality gate dielectric in the form of gate oxide 20,32 is then formed over the whole surface, arriving at the structure shown in FIG. 3.

A metal layer 18 is then deposited over the whole surface. Any suitable material may be used, which may be metal, metal alloy, metal silicide, or metal nitride. Instead of a metal layer any other conducting material suitable for forming a gate such as conducting polysilicon may be used. With FinFETs, there is generally no doping in the fin so the threshold voltage of the transistor is controlled by the work function of the metal gate. Accordingly, mid-gap work function metals are preferred, since these result in similar threshold voltages for both n- and p-type transistors, though other metals may be used if required. In the embodiment shown the metal layer 18 is of TiN metal.

The metal layer 18 and gate oxide layer 20,32 are then patterned to define a separate gate 36 and gate oxide 32 for a switch FET in gap 50, as well as first and second gate electrodes 46,48 above gate dielectric 18 in first and second regions 42,44 either side of the switch FET.

An implantation step deposits source and drain implants to form the sources and drains of both the switch 52 and FINFETs 54.

FIG. 4 illustrates the location of the implanted sources and drains in top view. The source 22 and drain 24 for the FINFETs 54 are arranged at longitudinally opposed ends of each fin 12. The source 38 and drain 40 for the switch FET 52 extend longitudinally in the gap 50 left for the switch FET 52. Since the source and drain 38,40 of the switch FET need to connect to the gates of the FINFETs, the source and drain 38,40 are arranged adjacent to the central region of the fins between source 22 and drain 24 implantations since this central region is in the final device the gate region of the FINFET.

Thus, a single implantation step forms the source 22, 38 and drain 24,40 of the FINFETs 54 and of the switch FET 52.

Spacers 56 are then formed on the switch FET 52 and the FinFETs (not shown). The spacers are provided on the top of the gate 36 of the switch FET 36 and on the sidewalls of the fins adjacent to the switch FET. The use of this step allows short circuits between the gates 46, 48, 36 of the FinFETs 54 and switch FET 52 to be avoided.

A contact 58 is then formed above the source and drain 38,40 of the switch FET to connect the source 38 and drain 40 to the first 46 and second 48 gate electrodes respectively.

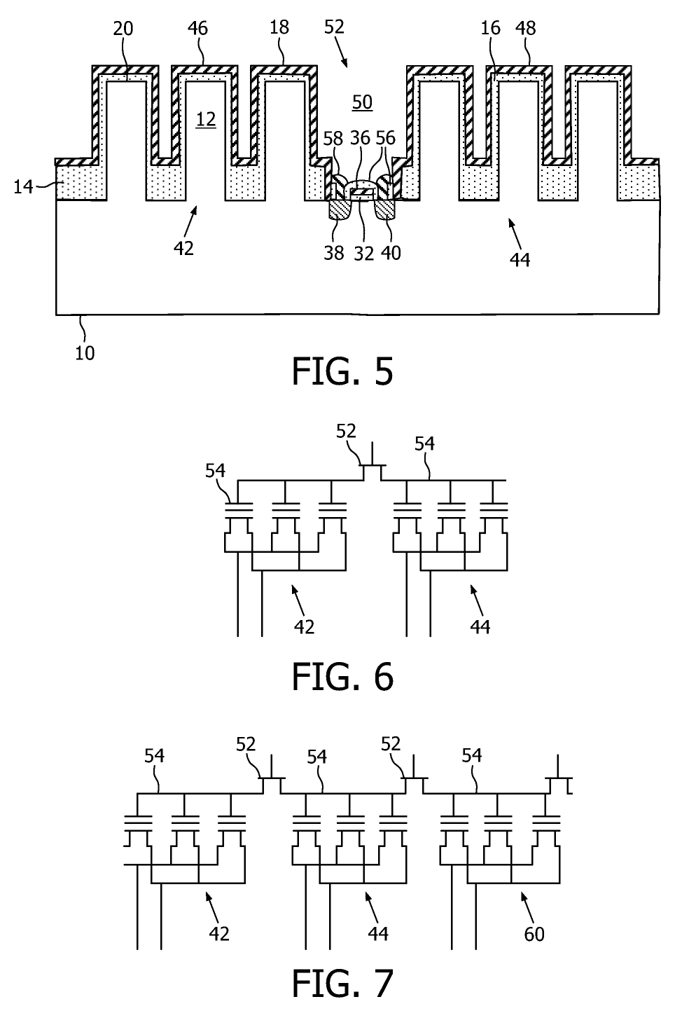

This final structure is illustrated in FIG. 5.

FIG. 6 shows a circuit diagram illustrating the FINFETs 54 in first and second regions 42, 44 connected by switch FET 52.

In use, the switch FET can be controlled by the voltage between the switch FET gate electrode and the semiconductor substrate 10 to be either on or off. In particular, if the voltage applied to the gate of the switch FET electrode exceeds the threshold voltage, the switch FET is on; conversely, with a lower voltage applied, the switch FET is off.

With the switch FET on, the first and second gate electrodes 46,48 are connected to one another and so the first and second regions 42, 44 of the FINFET operate together as a single transistor.

With the switch FET off, the first and second gate electrodes 46,48 are separate and may be separately controlled. In this way the first and second regions 42,44 of the FINFET act as separate transistors.

The FINFETs will conduct when switched on by virtue of the gate voltage applied to the FINFET gates 18. These create an inversion layer channel on both sides and the top of the fin 12. The top channel has different characteristics since the crystal orientation is different. In alternative embodiments a thicker oxide layer 16 is provided on the top surface of the fins 12 so that no inversion layer channel is formed on the top of the fin.

The transistor array according to the present invention is accordingly reconfigurable which allows a greater degree of flexibility to the designers.

The switch FET 52 acts as a normal switch and so the channel length and doping in the switch FET need not be controlled to a particularly high degree of accuracy.

The above embodiment is provided purely by way of example and variations are possible. For example, in the above embodiment various components of the FINFET and the switch FET are manufactured in the same steps; this reduces the number of steps. However, in alternative embodiments of the invention various stages in the manufacture of the switch FET 52 are separate to the manufacture of the FINFETs 54.

Those skilled in the art will appreciate that the details of the materials used and the exact manufacturing details may be varied as required.

In a particularly preferred embodiment, illustrated by a schematic circuit diagram in FIG. 7, the FINFET is divided into at least three regions 42, 44, 60 by a plurality of switch FETs 52 to further increase the flexibility of the device.

Optionally, different threshold voltages can be used for the different switch FETs to further increase flexibility.

The use of the term “array” of FINFETs should not be considered to limit the number of FINFETs; the invention may relate to a single FINFET on either side of a switch transistor, in which case the array of FINFETs only includes the two FINFETs, or to an array having a large number of FINFETs.

1. A semiconductor device, comprising:
a plurality of fin field effect transistors having sources, drains and gates, the fin field effect transistors including a first fin field effect transistor region with a common gate and a second fin field effect transistor region with a common gate; and
a switch field effect transistor between the first fin field effect transistor region and the second fin field effect transistor region, the switch field effect transistor having a source connected to the gates of one of the first and second fin field effect transistor regions and a drain connected to the other of the first and second fin field effect transistor regions, the switch field effect transistor having a gate so that the voltage on the gate of the switch field effect transistor can be controlled to selectably connect the gates of the first and second fin field effect transistor regions together.

2. A semiconductor device according to claim 1 comprising:
a semiconductor substrate having a first major surface;
wherein the fin field effect transistor includes:
a plurality of fins extending into the first major surface of the substrate, the fins being laterally spaced and extending longitudinally along the first major surface;
longitudinally spaced sources and drains provided on the fins;
a gate dielectric extending over the fins;
a buried oxide layer between the fins; and
a gate extending over the gate dielectric between the source and drain implants; and
the switch field effect transistor is provided between fins;
wherein the switch field effect transistor, a gate oxide and a gate extending over the gate oxide between the source and drain of the switch field effect transistor.

3. A semiconductor device according to claim 1 further comprising a plurality of switch field effect transistors between at least three regions of the fin field effect transistors.

4. A method of operation of a semiconductor device according to claim 1, comprising:
applying a voltage between the substrate and the gate of the switch field effect transistor to control the switch field effect transistor to be selectably in a single unit mode of operation or a multiple unit mode of operation; wherein:
in the single unit mode of operation the switch field effect transistor is switched on to connect the regions of the switch field effect transistor so that the switch field effect transistor operates as a single unit;
in the multiple unit mode of operation the switch field effect transistor is switched off to disconnect the regions of the switch field effect transistor so that the switch field effect transistor operates as a plurality of units.

5. A method of making a semiconductor device, comprising:
forming a plurality of fin field effect transistors having sources, drains and gates, the fin field effect transistors including a first fin field effect transistor region with a common gate and a second fin field effect transistor region with a common gate; and
forming a switch field effect transistor between the first fin field effect transistor regions and the second fin field effect transistor region, the switch field effect transistor having a source connected to the gates of one of the first and second fin field effect transistor regions and a drain connected to the other of the first and second fin field effect transistor regions, the switch field effect transistor having a gate so that the voltage on the gate of the switch field effect transistor can be controlled to selectably connect the gates of the first and second fin field effect transistor regions together.

6. A method of making a semiconductor device according to claim 5, comprising:
providing a semiconductor substrate having a first major surface;
etching a plurality of fins into the first major surface of the substrate, the fins being laterally spaced and extending longitudinally along the first major surface for forming the fin field effect transistors, the fins defining at least one space between fins for forming the switch fin field effect transistor;
depositing oxide to form a buried oxide layer between the fins;
forming a gate dielectric over the fins;
forming a gate dielectric of the switch field effect transistor in the space between fins;
depositing a gate conductor over the gate dielectric over the fins to form the gate of the fin field effect transistors; and
forming a gate over the gate dielectric of the switch field effect transistor.

7. A method of making a semiconductor device according to claim 6 further comprising carrying out a single implantation to form the sources and drains of the fin field effect transistors as well as source and drain implants in the space between fins to form the source and the drain of at least one switch field effect transistors.

8. A method of making a semiconductor device according to claim 6 wherein the step of depositing oxide and forming the gate oxide use a single oxidation step to form the gate oxide of the fin field effect transistor and the gate oxide of the switch FET.

9. A method of making a semiconductor device according to claim 6 wherein the steps of depositing a gate conductor and forming a gate of the switch field effect transistor use a single deposition to form a gate of the switch field effect transistor.

10. A method according to claim 6 comprising forming a plurality of switch field effect transistors between at least three regions the of the fin field effect transistors.
